(19) United States
(12) Patent Application Publication
(10) Pub. No.: US 2008/0017917 A1
(43) Pub. Date: Jan. 24, 2008

(54) NON-VOLATILE MEMORY AND FABRICATING METHOD THEREOF

(75) Inventors: Chrong-Jung Lin, Taipei County (TW); Hsin-Ming Chen, Tainan County (TW); Ya-Chin King, Taoyuan County (TW)

Correspondence Address: J C PATENTS, INC., 4 VENTURE, SUITE 250, IRVINE, CA, 92618, US

(73) Assignee: EMEMORY TECHNOLOGY INC., Hsin-Chu (TW)

(21) Appl. No.: 11/778,226

(22) Filed: Jul. 16, 2007

Related U.S. Application Data
(60) Provisional application No. 60/807,615, filed on Jul. 18, 2006.

(51) Int. Cl. H01L 29/788; H01L 21/3205

(52) U.S. Cl. 257/321; 438/585; 257/E21.294; 257/E29.3

(57) ABSTRACT

A non-volatile memory having an isolation structure, a floating gate transistor, a specific dielectric layer and an erase gate is provided. The isolation structure is disposed in a substrate to define an active region. The floating gate transistor having a floating gate, a tunneling dielectric layer, a first source/drain region and a second source/drain region is disposed on the substrate. The floating gate is disposed on the substrate and runs across the active region. The tunneling dielectric layer is disposed between the floating gate and the substrate. The first source/drain region and the second source/drain region are disposed in the substrate at the sides of the floating gate, respectively. The specific dielectric layer serves as an inter-layer dielectric layer, which is disposed on top of the floating gate. The erase gate is a conductive plug disposed upon the specific dielectric layer.

### CROSS-REFERENCE TO RELATED APPLICATION

This application claims the priority benefit of U.S.A. provisional application Ser. No. 60/807,615, filed on Jul. 18, 2006, all disclosures are incorporated herein by reference.

### BACKGROUND OF THE INVENTION

1. Field of the Invention

The present invention generally relates to a semiconductor device, and more particularly, to a non-volatile memory and fabricating method thereof.

2. Description of Related Art

When semiconductor process proceeds into deep sub-micron regime, the dimension of devices is gradually reduced. For memory devices, this trend implies that the dimension of memory cells is becoming smaller. On the other hand, with the ever-increasing amount of data that needs to be processed and saved by information electronic products (for example, computer, mobile phone, digital camera or personal digital assistant (PDA)), the required memory capacity of these information electronic products is becoming larger. Subjected to the constraints of a smaller device dimension but a larger memory capacity, how to fabricate memory device having smaller dimension, higher integration and better quality has become a common goal of the industry.

Because non-volatile memory has the advantage of retaining stored data even after power to the device is cut off, it has been broadly applied in personal computer and electronic equipment.

A typical non-volatile memory device has a floating gate and a control gate fabricated using doped polysilicon to form a stacked structure. A dielectric layer is disposed between the floating gate and the substrate and between the floating gate and the control gate, respectively.

However, in the fabrication of the foregoing non-volatile memory, a plurality of polysilicon layers and a plurality of dielectric layers, which require a number of photo-masking steps, are required. Hence, not only is the throughput of the fabrication process decreased, but also the fabrication cost is increased.

In U.S. Pat. No. 6,678,190, a non-volatile memory is disclosed. For this type of non-volatile memory, there is no need to form a plurality of polysilicon layers and two serially connected P-type metal-oxide-semiconductor (MOS) transistors disposed on an N-well serve as the select gate and the floating gate. Because there is no need to form the control gate, the process of this non-volatile memory can be combined with the process of complementary metal-oxide-semiconductor (CMOS) transistor to save fabrication cost.

For non-volatile memory having single-layer polysilicon, performing programming or reading operation is not a problem. However, when performing an erase operation, a voltage is normally applied to the well region so that the well voltage is capacitively coupled to the floating gate so as to generate a sufficient voltage difference between the floating gate and the well region to guide the electrons through the tunnel dielectric layer into the well region and then be removed. Because, electrons also pass through the tunnel dielectric layer into the floating gate or out of the floating gate when performing a programming operation or an erase operation of this type of non-volatile memory, the tunnel dielectric layer is easily damaged and leads to a leakage current. As a result, the reliability of the memory device is lowered. In addition, with the increase in device integration and memory density, higher leakage current will be generated so that the effort to reduce the dimension of devices can be significantly compromised. Another disadvantage of using well voltage coupling is that the coupling efficiency may be low, which leads to the need to apply a relatively large well voltage. The single-layer polysilicon non-volatile memory may require a high voltage module. Consequently, the process becomes more complicated and the fabrication cost is increased.

### SUMMARY OF THE INVENTION

Accordingly, the present invention is directed to non-volatile memory having a conductive plug disposed on an inter-layer dielectric layer above a floating gate to serve as an erase gate so that programming operation and erasing operation can be repeatedly performed on the non-volatile memory. Because, the electric charges in the programming operation and the erasing operation are not entering in or exiting out through the tunnel dielectric layer alone, the reliability of the non-volatile memory is improved. Furthermore, the erasing action is achieved through a direct application to the conductive plug on the inter-layer dielectric layer above the floating gate, the coupling efficiency is high so that the erase voltage can be reduced and process complication can be minimized.

The present invention is also directed to a method of fabricating non-volatile memory capable of fabricating non-volatile memory without changing the conventional complementary metal-oxide-semiconductor (CMOS) process and yet capable of increasing the integration of memory devices.

According to an embodiment of the present invention, a non-volatile memory disposed on a substrate is provided. The non-volatile memory has an isolation structure, a floating gate transistor, a specific dielectric layer and an erase gate. The isolation structure is disposed in a substrate to define an active region. The floating gate transistor having a floating gate, a tunneling dielectric layer, a first source/drain region and a second source/drain region is disposed on the substrate. The floating gate is disposed on the substrate and runs across the active region. The tunneling dielectric layer is disposed between the floating gate and the substrate. The first source/drain region and the second source/drain region are disposed in the substrate at the sides of the floating gate, respectively. The specific dielectric layer serves as an inter-layer dielectric layer, which is disposed on top of the floating gate. The erase gate is a first conductive plug disposed on the specific dielectric layer.

According to an embodiment of the present invention, the specific dielectric layer covers a portion of the floating gate.

According to an embodiment of the present invention, the specific dielectric layer completely covers the floating gate.

According to an embodiment of the present invention, the material of the specific dielectric layer includes silicon oxide or silicon oxynitride.

According to an embodiment of the present invention, the erase gate is disposed at one end of the floating gate and located above the isolation structure.

According to an embodiment of the present invention, the non-volatile memory further includes a second conductive plug and a third conductive plug electrically connected to the first source/drain region and the second source/drain region, respectively.

According to an embodiment of the present invention, the non-volatile memory further includes a select gate transistor disposed on the substrate and serially connected to the floating gate transistor. The select gate transistor has a select gate, a gate dielectric layer, a third source/drain region and a second source/drain region. The select gate is disposed on the substrate and runs across the active region. The gate dielectric layer is disposed between the select gate and the substrate. The third source/drain region and the second source/drain region are disposed in the substrate at the sides of the select gate, respectively.

According to an embodiment of the present invention, the specific dielectric layer covers a portion of the floating gate.

According to an embodiment of the present invention, the specific dielectric layer covers the whole floating gate.

According to an embodiment of the present invention, the material of the specific dielectric layer includes silicon oxide or silicon oxynitride.

According to an embodiment of the present invention, the erase gate is disposed at one end of the floating gate and located above the isolation structure.

According to an embodiment of the present invention, the non-volatile memory further includes a second conductive plug and a third conductive plug electrically connected to the first source/drain region and the third source/drain region, respectively.

The non-volatile memory of the present invention has a first conductive plug disposed on the inter-layer dielectric layer above the floating gate, and the first conductive plug can serve as an erase gate. Moreover, using the specific dielectric layer (a self-aligned salicide block oxide or a resistive-protective oxide) as an inter-layer dielectric layer between the floating gate and the first conductive plug (the erase gate), the non-volatile memory can be fabricated without changing the conventional CMOS process.

Furthermore, when a voltage is applied to the first conductive plug (the erase gate), it is coupled to the floating gate, and a sufficiently large voltage difference between the floating gate and the first conductive plug (the erase gate) is formed to induce F-N tunneling effect. Therefore, electrons from the floating gate can tunnel through the specific dielectric layer (a self-aligned salicide block oxide or a resistive-protective oxide) into the first conductive plug (the erase gate) so that the memory is erased. Another approach is to establish a sufficiently large voltage difference between the floating gate and well by applying a smaller voltage to first conductive plug (the erase gate) and a larger voltage to well bias. Small capacitive coupling between the floating gate and first conductive plug (the erase gate) will lead to a sufficiently large voltage difference between the floating gate and well. Therefore, by setting up the erase gate, programming operation and erasing operation can be repeatedly performed on the non-volatile memory of the present invention.

In addition, if the first conductive plug (the erase gate) is disposed at one end of the floating gate so that the overlapping area between the first conductive plug (the erase gate) and the floating gate is reduced, a lower coupling efficiency is obtained. With a lower coupling efficiency, the speed of the memory erasing operation by tunneling electrons out of floating gate to the well regime is increased.

The present invention also provides a method of fabricating non-volatile memory that includes the following steps. First, a substrate having a floating gate transistor formed thereon is provided. The floating gate transistor has a floating gate, a tunneling dielectric layer, a first source/drain region and a second source/drain region. Next, a specific dielectric layer is formed on the substrate and then a portion of the specific dielectric layer is removed so as to retain only the specific dielectric layer above the floating gate. Thereafter, a first conductive plug is formed on the specific dielectric layer, wherein the first conductive plug serves as an erase gate.

According to an embodiment of the present invention, the step of removing a portion of the specific dielectric layer so as to retain only the specific dielectric layer above the floating gate is as follows. First, a mask layer is formed over the substrate to cover the floating gate. Thereafter, a portion of the specific dielectric layer is removed using the mask layer as a mask. Next, the mask layer is removed.

According to an embodiment of the present invention, the method further includes forming an inter-layer insulating layer on the substrate before forming the first conductive plug on the specific dielectric layer.

According to an embodiment of the present invention, the specific dielectric layer covers a portion of the floating gate.

According to an embodiment of the present invention, the specific dielectric layer covers the whole floating gate.

According to an embodiment of the present invention, the step of forming the conductive plug on the specific dielectric layer further includes forming a second conductive plug and a third conductive plug for electrically connecting the first source/drain region and the second source/drain region, respectively.

According to an embodiment of the present invention, the specific dielectric layer includes silicon oxide or silicon oxynitride.

According to an embodiment of the present invention, the method further includes forming a select gate transistor on the substrate. The select gate transistor is serially connected to the floating gate transistor. The select gate transistor has a select gate, a gate dielectric layer and a third source/drain region and a second source/drain region.

According to an embodiment of the present invention, the step of removing portion of the specific dielectric layer so as to retain only the specific dielectric layer above the floating gate is as follows. First, a masking layer is formed over the substrate to cover the floating gate. Next, a portion of the specific dielectric layer is removed using the masking layer as a mask. Next, the masking layer is removed.

According to an embodiment of the present invention, the method further includes forming an inter-layer insulating layer on the substrate before forming the first conductive plug on the specific dielectric layer.

According to an embodiment of the present invention, the specific dielectric layer covers a portion of the floating gate.

According to an embodiment of the present invention, the specific dielectric layer covers the whole floating gate.

According to an embodiment of the present invention, the step of forming the first conductive plug on the specific dielectric layer further includes forming a second conductive plug and a third conductive plug for electrically connecting to the first source/drain region and the third source/drain region, respectively.

According to an embodiment of the present invention, the material of the specific dielectric layer includes silicon oxide or silicon oxynitride.

In the method of fabricating non-volatile memory according to the present invention, a first conductive plug is formed on top of the floating gate to serve as an erase gate. Moreover, the specific dielectric layer (a self-aligned salicide block oxide or a resistive-protective oxide) is used as an inter-layer dielectric layer between the floating gate and the first conductive plug (the erase gate). The first conductive plug can be fabricated together with the second conductive plug and the third conductive plug that are connected to the source/drain regions of the transistor in the same process. Therefore, the non-volatile memory can be fabricated without changing the conventional CMOS process. Furthermore, the first conductive plug (the erase gate) is directly formed on the inter-layer dielectric layer above the floating gate. Therefore, the integration of the semiconductor devices can be effectively increased and do not occupy additional space and additional masking layers.

### BRIEF DESCRIPTION OF THE DRAWINGS

The accompanying drawings are included to provide a further understanding of the invention, and are incorporated in and constitute a portion of this specification. The drawings illustrate embodiments of the invention and, together with the description, serve to explain the principles of the invention.

FIG. 1A is a top view of a non-volatile memory according to an embodiment of the present invention.

FIG. 1B is a schematic cross-sectional view along line A-A′ of FIG. 1A.

FIG. 1C is a schematic cross-sectional view along line B-B′ of FIG. 1A.

FIG. 2A is a top view of a non-volatile memory according to another embodiment of the present invention.

FIG. 2B is a schematic cross-sectional view along line A-A′ of FIG. 2A.

FIG. 2C is a schematic cross-sectional view along line B-B′ of FIG. 2A.

FIG. 3A is a top view of a non-volatile memory according to yet another embodiment of the present invention.

FIG. 3B is a schematic cross-sectional view along line A-A′ of FIG. 3A.

FIG. 3C is a schematic cross-sectional view along line B-B′ of FIG. 3A.

FIGS. 4A to 4D are schematic cross-sectional views showing a method of fabricating a non-volatile memory according to an embodiment of the present invention.

FIGS. 5A to 5D are schematic cross-sectional views showing a method of fabricating a non-volatile memory according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

First, the non-volatile memory of the present invention is described.

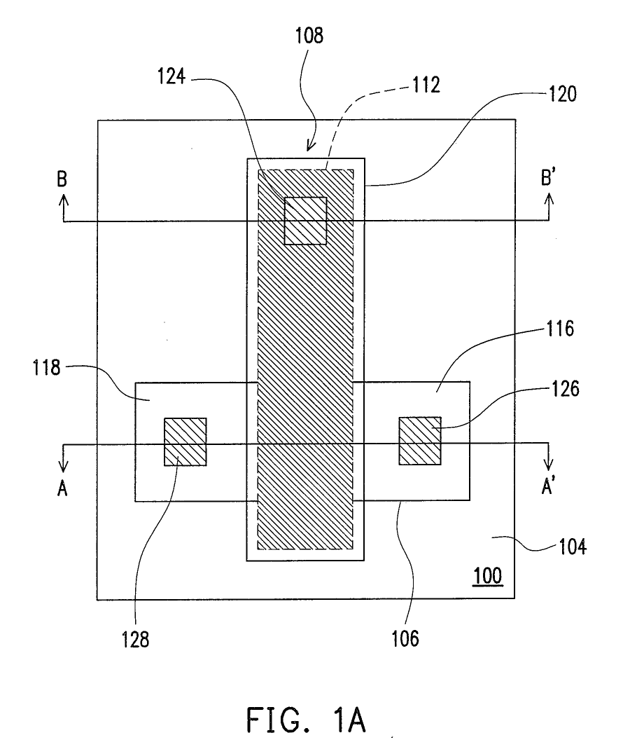

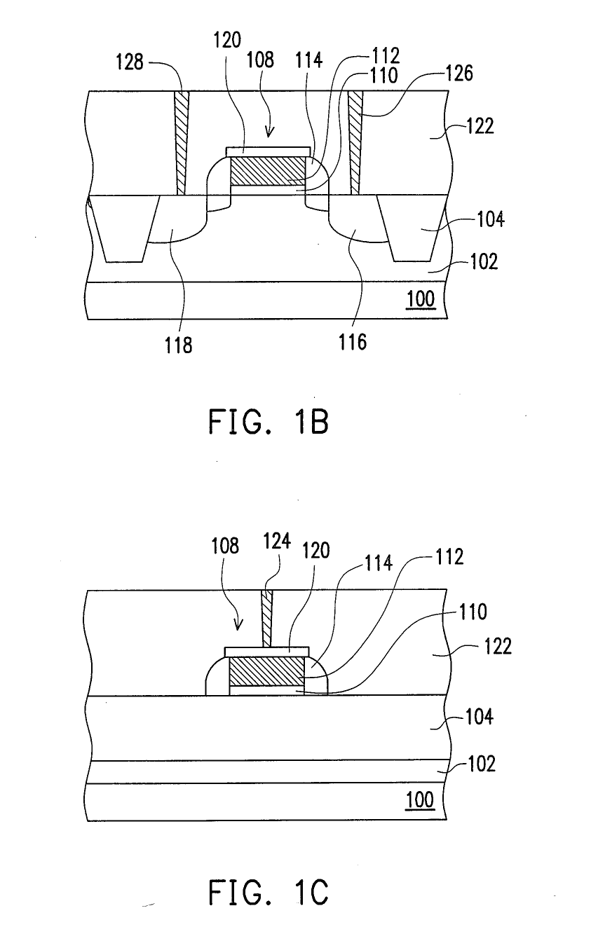

FIG. 1A is a top view of a non-volatile memory according to an embodiment of the present invention. FIG. 1B is a schematic cross-sectional view along line A-A′ of FIG. 1A. FIG. 1C is a schematic cross-sectional view along line B-B′ of FIG. 1A.

As shown in FIGS. 1A to 1C, the non-volatile memory of the present invention is disposed on a substrate 100, for example. The substrate 100 is a silicon substrate and has a well region 102, for example. Furthermore, the substrate 100 has an isolation structure 104 that defines an active region 106. The isolation structure 104 is, for example, a shallow trench isolation (STI) structure or a field oxide layer.

The non-volatile memory, according to an embodiment of the present invention includes a floating gate transistor 108, a specific dielectric layer 120 and a conductive plug 124 (an erase gate).

The floating gate transistor 108 is disposed on the substrate 100, for example. The floating gate transistor 108 includes a tunneling dielectric layer 110, a floating gate 112, a source/drain region 116, a source/drain region 118, a specific dielectric layer 120 and a conductive plug 124.

The floating gate 112 is disposed on the substrate 100 and runs across the active region 106, for example. Therefore, a portion of the floating gate 112 is located on the isolation structure 104. The material of the floating gate 112 is doped polysilicon, for example.

The tunneling dielectric layer 110 is disposed between the floating gate 112 and the substrate 100, for example. The material of the tunneling dielectric layer is silicon oxide, for example. Furthermore, spacers 114 may also be disposed on the sidewalls of the floating gate 112 and the tunneling dielectric layer 110. The material of the spacers 114 is silicon oxide, silicon nitride or silicon and silicon nitride's combination, for example.

The source/drain region 116 and the source/drain region 118 are disposed in the substrate 100 at two sides of the floating gate 112, for example. The source/drain region 116 and the source/drain region 118 are located in the active region 106.

The specific dielectric layer 120 is disposed on the floating gate 112, for example. The specific dielectric layer 120 may cover a portion of the floating gate 112 or cover the whole floating gate 112. For example, the specific dielectric layer 120 may be disposed only between the conductive plug 124 and the floating gate 112. The material of the specific dielectric layer is silicon oxide or silicon oxynitride, for example.

The conductive plug 124 is disposed on the specific dielectric layer 120, for example. Furthermore, the conductive plug 124 is disposed at one end of the floating gate 112 and located above the isolation structure 104. In the present invention, the conductive plug 124 serves as an erase gate. The material of the conductive plug includes a conductive material, for example, a metal material or doped polysilicon.

In addition, a conductive plug 126 and a conductive plug 128 are also disposed on the source/drain region 116 and the source/drain region 118, respectively. The conductive plug 126 and the conductive plug 128 are electrically connected to the source/drain region 116 and the source/drain region 118, respectively. The material of the conductive plug 126 and the conductive plug 128 includes a conductive material, for example, a metal or doped polysilicon. The conductive plug 124, the conductive plug 126 and the conductive plug 128 are formed in the same process.

Moreover, the conductive plug 124, the conductive plug 126 and the conductive plug 128 are disposed in an inter-layer insulating layer 122, for example. The material of the inter-layer insulating layer 122 is phosphosilicate glass or borophosphosilicate glass, for example.

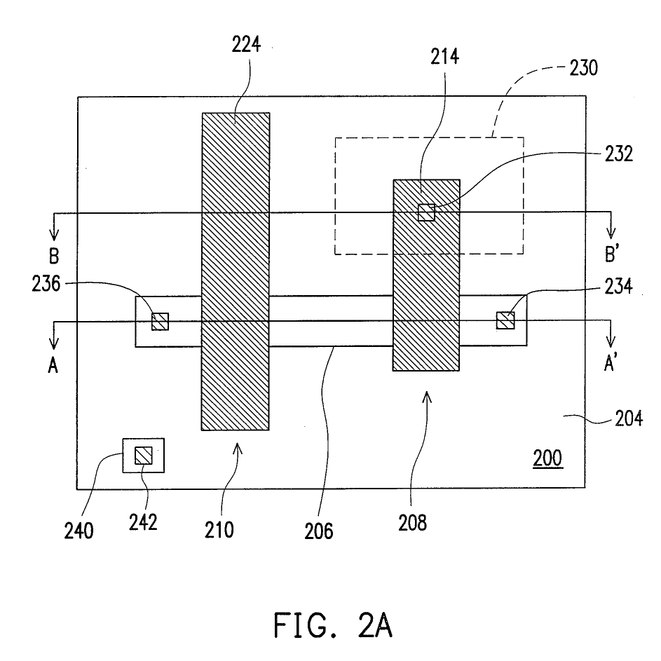

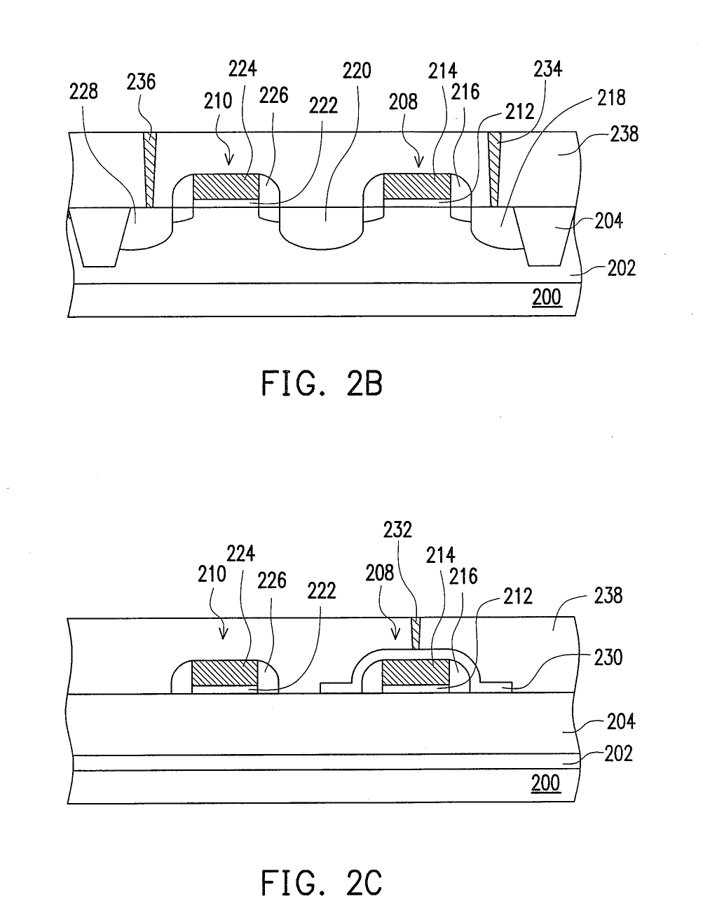

FIG. 2A is a top view of a non-volatile memory according to another embodiment of the present invention. FIG. 2B is a schematic cross-sectional view along line A-A′ of FIG. 2A. FIG. 2C is a schematic cross-sectional view along line B-B′ of FIG. 2A.

As shown in FIGS. 2A to 2C, the non-volatile memory of the present invention is disposed on a substrate 200, for example. The substrate 200 is a silicon substrate and has a well region 202, for example. Furthermore, the substrate 200 has an isolation structure 204 that defines an active region 206. The isolation structure 204 is a shallow trench isolation (STI) structure or a field oxide layer, for example.

The non-volatile memory, according to an embodiment of the present invention, includes a floating gate transistor 208 and a select gate transistor 210, a specific dielectric layer 230 and a conductive plug 232 (an erase gate). The floating gate transistor 208 and the select gate transistor 210 are disposed on the substrate 200 and serially connected together, for example.

The floating gate transistor 208 includes a tunneling dielectric layer 212, a floating gate 214, a source/drain region 218 and a source/drain region 220.

The floating gate 214 is disposed on the substrate 200 and runs across the active region 206, for example. Therefore, a portion of the floating gate 214 is located above the isolation structure 204. The material of the floating gate 214 is doped polysilicon, for example.

The tunneling dielectric layer 212 is disposed between the floating gate 214 and the substrate 200, for example. The material of the tunneling dielectric layer 212 is silicon oxide, for example. Furthermore, spacers 216 may be disposed on the sidewalls of the floating gate 214 and the tunneling dielectric layer 212. The material of the spacers 216 is silicon oxide, silicon nitride or silicon oxide and silicon nitride's combination, for example.

The source/drain region 218 and the source/drain region 220 are disposed in the substrate 200 at two sides of the floating gate 214, respectively, for example. Furthermore, the source/drain region 218 and the source/drain region 220 are located in the active region 206.

The select gate transistor 210 includes a gate dielectric layer 222, a select gate 224, a source/drain region 220 and a source/drain region 228, for example.

The select gate 224 is disposed on the substrate 200 and runs across the active region 206, for example. The material of the select gate 224 is doped polysilicon, for example.

The gate dielectric layer 222 is disposed between the select gate 224 and the substrate 200, for example. The material of the gate dielectric layer 222 is silicon oxide, for example. Furthermore, spacers 226 may be disposed on the sidewalls of the select gate 224 and the gate dielectric layer 222. The material of the spacers 226 is silicon oxide, silicon nitride or silicon oxide and silicon nitride's combination, for example.

The source/drain region 220 and the source/drain region 228 are disposed in the substrate 200 at the sides of the select gate 224, respectively, for example. Furthermore, the source/drain region 220 and the source/drain region 228 are located in the active region 206. Both the floating gate transistor 208 and the select gate transistor 210 use the same source/drain region 220.

The specific dielectric layer 230 is disposed on the floating gate 214, for example. The specific dielectric layer only covers a portion of the floating gate 214 and does not cover the floating gate 214 located above the active region 206. Obviously, the specific dielectric layer 230 may also be disposed only between the conductive plug 232 and the floating gate 214. The material of the specific dielectric layer 230 is silicon oxide or silicon oxynitride, for example.

In the present invention, the so-called specific dielectric layer 230 is film that serves as a self-aligned salicide block oxide (SAB) in a logic process. In a semiconductor device process, the wafer is normally divided into a main device region and a peripheral circuit region. The devices in the main device region include memory devices and electrostatic discharge (ESD) protection circuits, and the devices in the peripheral circuit region are logic devices, for example. In general, the electrical characteristics of the devices in the main device region and the devices in the peripheral circuit region are different. Therefore, a silicide process is normally performed after forming the devices so as to form silicide layers on the gate layers and the source/drain regions for reducing device resistance. However, before performing the silicide process, a film (the specific dielectric layer 230) is employed to cover those areas that need not be exposed to the silicide reaction. Because, the specific dielectric layer 230 (a self-aligned salicide block oxide or a resistive-protective oxide) commonly used in a logic process is directly used as the inter-layer dielectric layer between the floating gate and the conductive plug (the erase gate), the non-volatile memory of the present invention can be fabricated without changing the conventional CMOS process. In addition, the integration of memory devices is increased and the memory devices do not occupy additional space or additional masking layers.

The conductive plug 232 is disposed on the specific dielectric layer 230, for example. Furthermore, the conductive plug 232 is disposed at one end of the floating gate 214 and located above the isolation structure 204. In the present invention, the conductive plug 232 serves as an erase gate.

In addition, a conductive plug 234 and a conductive plug 236 are disposed on the source/drain region 218 and the source/drain region 228, respectively. The conductive plug 234 and the conductive plug 236 are electrically connected to the source/drain region 218 and the source/drain region 228, respectively. The material of the conductive plug 234 and the conductive plug 236 includes a conductive material, for example, metal or doped polysilicon. The conductive plug 232, the conductive plug 234 and the conductive plug 236 are formed in the same process.

Furthermore, the conductive plug 232, the conductive plug 234 and the conductive plug 236 are disposed in an inter-layer insulating layer 238, for example. The material of the inter-layer insulating layer is phosphosilicate glass or borophosphosilicate glass, for example.

In addition, as shown in FIG. 2A, a pullout region 240 of the well region may be disposed in the substrate 200. This well pullout region 240 is connected to the well region 202. A conductive plug 242 is disposed on the well pullout region 240, for example. The conductive plug 242 is electrically connected to the well region 202.

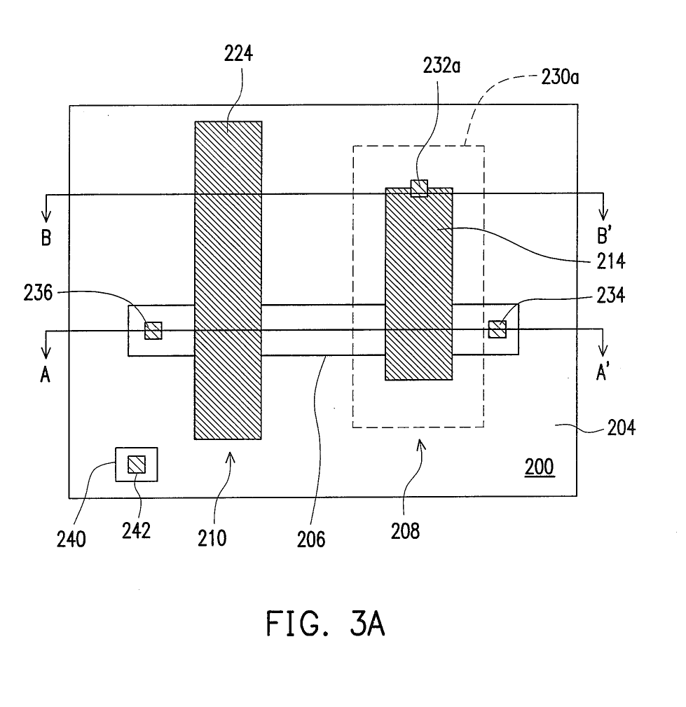

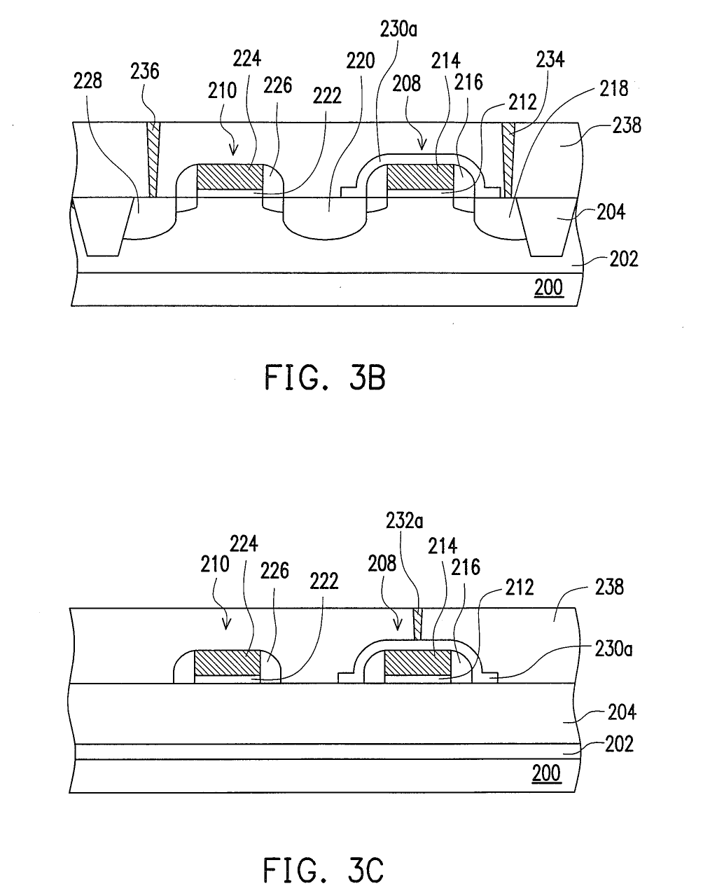

FIG. 3A is a top view of a non-volatile memory according to yet another embodiment of the present invention. FIG. 3B is a schematic cross-sectional view along line A-A′ of FIG. 3A. FIG. 3C is a schematic cross-sectional view along line B-B′ of FIG. 3A. In FIGS. 3A to 3C, components that are identical to the ones in FIGS. 2A to 2C are labeled identically and their descriptions are omitted.

As shown in FIGS. 3A to 3C, the non-volatile memory, according to an embodiment of the present invention, is disposed on a substrate 200, for example. The substrate 200 is a silicon substrate and has a well region 202, for example. Furthermore, the substrate 200 has an isolation structure 204 that defines an active region 206.

The non-volatile memory includes a floating gate transistor 208 and a select gate transistor 210, a specific dielectric layer 230a and a conductive plug 232a (an erase gate). The floating gate transistor 208 and the select gate transistor 210 are disposed on the substrate 200 and serially connected together, for example.

The floating gate transistor 208 includes a tunneling dielectric layer 212, a floating gate 214, a source/drain region 218 and a source/drain region 220, for example. Spacers 216 are formed on the sidewalls of the floating gate 214 and the tunneling dielectric layer 212, for example. The select gate transistor 210 includes a gate dielectric layer 222, a select gate 224, a source/drain region 220 and a source drain region 228, for example. Spacers 226 may also be disposed on the sidewalls of the select gate 224 and the gate dielectric layer 222. Both the floating gate transistor 208 and the select gate transistor use the same source/drain region 220.

The specific dielectric layer 230a is disposed on the floating gate 214, for example. Furthermore, the conductive plug 232a is disposed at one end of the floating gate 214 and located above the isolation structure 204. In the present invention, the conductive plug 232a serves as an erase gate. Since the conductive plug 232a is disposed at one end of the floating gate 214, the overlapping area between the floating gate 214 and the conductive plug 232a is reduced. In other words, the speed of the memory erasing operation is increased. Obviously, the conductive plug 232a can be disposed anywhere on the specific dielectric layer 230a where there exists some overlapping portion with the floating gate and the conductive plug 232a.

In addition, a conductive plug 234 and a conductive plug 236 are disposed on the source/drain region 218 and the source/drain region 228, respectively. The conductive plug 234 and the conductive plug 236 are electrically connected to the source/drain region 218 and the source/drain region 228, respectively. Furthermore, the conductive plug 232, the conductive plug 234 and the conductive plug 236 are disposed on an inter-layer insulating layer 238, for example.

Moreover, as shown in FIG. 3A, a well pullout region 240 may be disposed in the substrate 200. The well pullout region 240 is connected to the well region 202. A conductive plug 242 is disposed on the well pullout region 240, for example. The conductive plug 242 is electrically connected to the well region 202.

The non-volatile memory, according to an embodiment of the present invention, includes a conductive plug disposed on the inter-layer dielectric layer above the floating gate, and this conductive plug can serve as an erase gate. Moreover, using the specific dielectric layer (a self-aligned salicide block oxide or a resistive-protective oxide) as an inter-layer dielectric layer between the floating gate and the conductive plug (the erase gate), the non-volatile memory can be fabricated without changing the conventional CMOS process.

Furthermore, when a voltage is applied to the conductive plug (the erase gate), it is coupled to the floating gate and a sufficiently large voltage difference between the floating gate and the conductive plug (the erase gate) is formed to generate F-N tunneling effect. Therefore, electrons from the floating gate can tunnel through the specific dielectric layer (a self-aligned salicide block oxide or a resistive-protective oxide) into the conductive plug (the erase gate) so that the memory is erased. Another approach is to establish a sufficiently large voltage difference between the floating gate and well by applying a smaller voltage to first conductive plug (the erase gate) and a larger voltage to well bias. Small capacitive coupling between the floating gate and first conductive plug (the erase gate) will lead to a sufficiently large voltage difference between the floating gate and well. Therefore, by setting up the erase gate, programming operation and erasing operation can be repeatedly performed on the non-volatile memory of the present invention.

In addition, the conductive plug (the erase gate) is disposed at one end of the floating gate so that the overlapping area between the conductive plug (the erase gate) and the floating gate is reduced. With a reduction in the overlapping area between the floating gate and erase gate, the speed of the memory erasing operation is increased.

Next, another method of fabricating a non-volatile memory of the present invention is described.

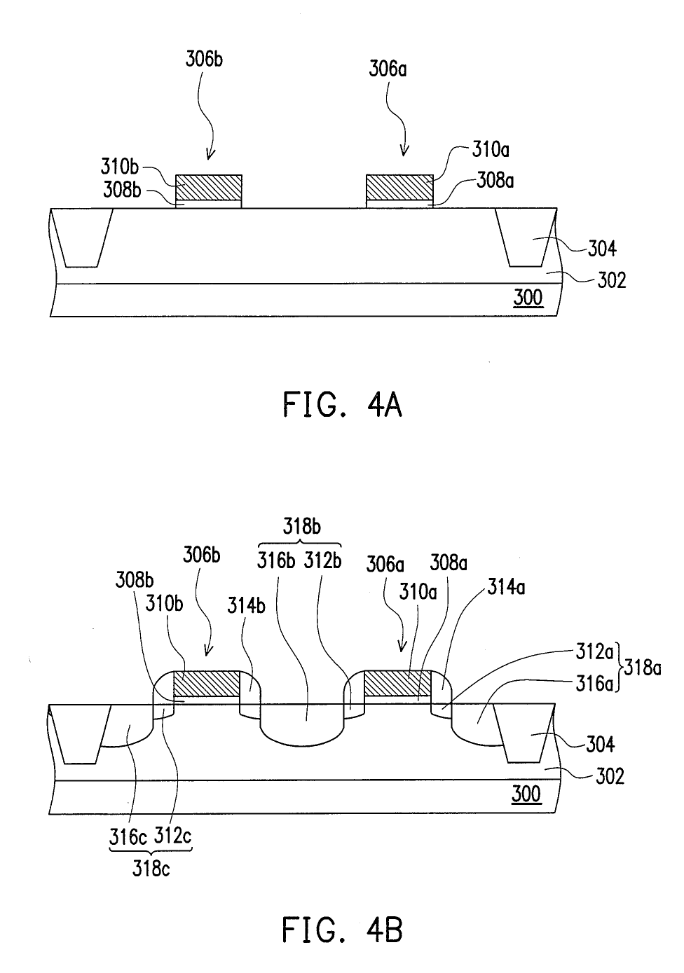

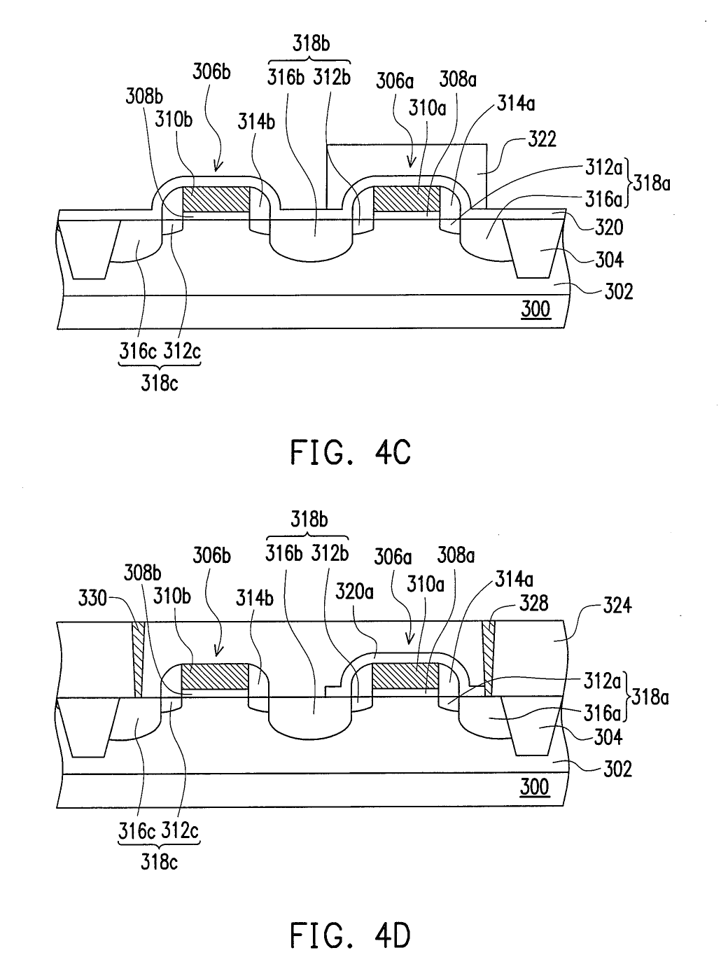

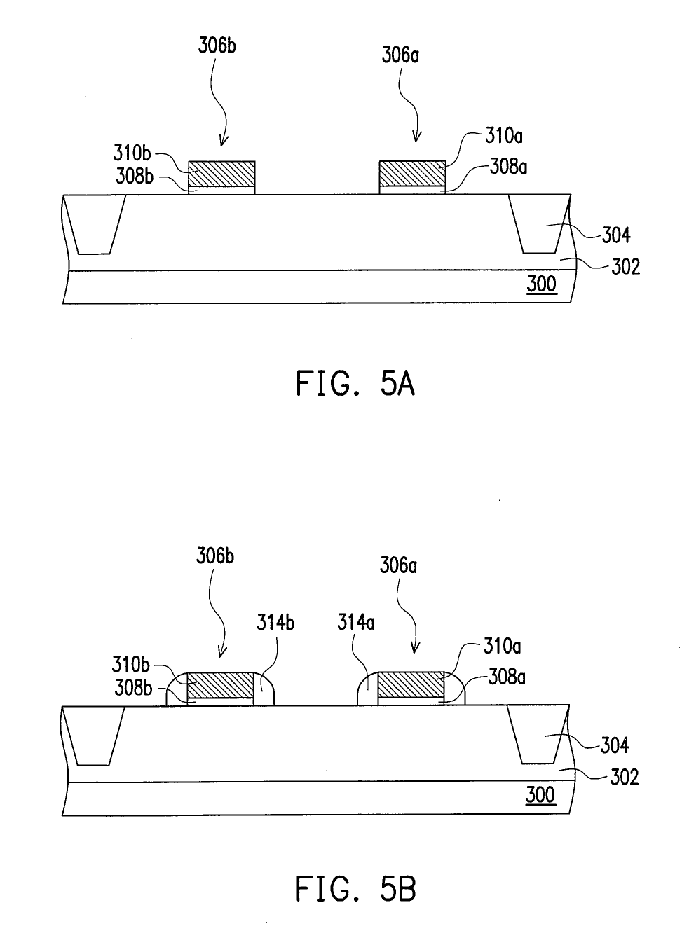

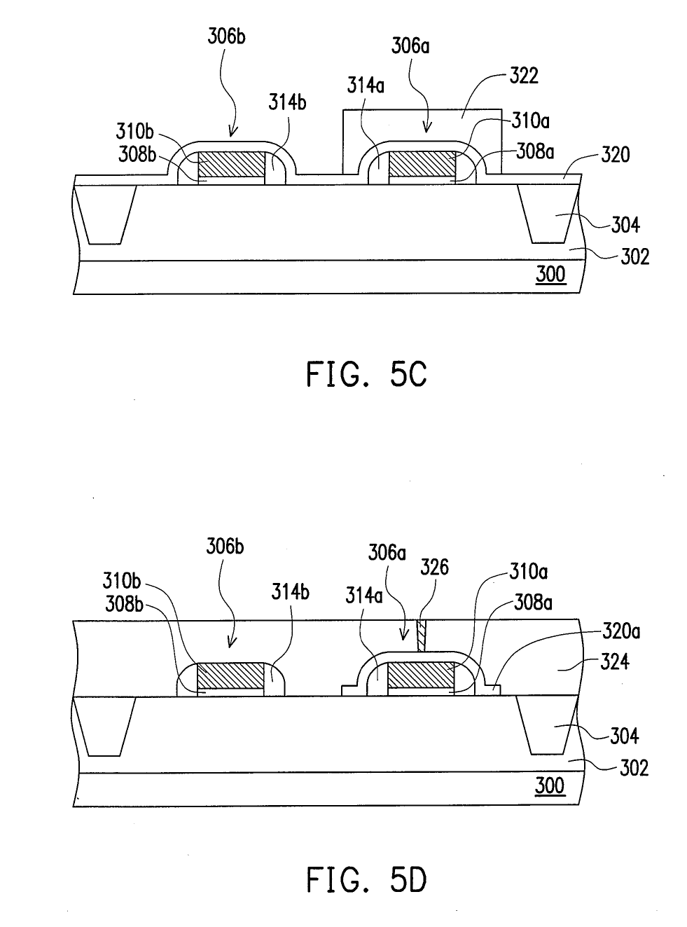

FIGS. 4A to 4D are schematic cross-sectional views showing a method of fabricating a non-volatile memory according to an embodiment of the present invention. FIGS. 5A to 5D are schematic cross-sectional views showing a method of fabricating a non-volatile memory according to an embodiment of the present invention. In fact, FIGS. 4A to 4D correspond to schematic cross-section views along line A-A′ of FIG. 3A and FIGS. 5A to 5D correspond to schematic cross-sectional views along line B-B′ of FIG. 3A.

As shown in FIGS. 4A and 5A, a substrate 300 is provided. The substrate 300 is a silicon substrate and has a well region 302, for example. The method of forming the well region 302 is, for example, performing an ion implant process. Next, an isolation structure 304 is formed in the substrate 300. The isolation structure 304 is a shallow trench isolation (STI) structure, for example.

Next, a gate structure 306a and a gate structure 306b are formed on the substrate 300. The gate structure 306a includes a tunneling dielectric layer 308a and a floating gate 310a. The gate structure 306b includes a gate dielectric layer 308b and a select gate 310b. The method of forming the gate structure 306a and the gate structure 306b includes, for example, sequentially forming a dielectric layer and a conductive material layer on the substrate 300 and performing a photolithographic and etching process to pattern the conductive material layer and the dielectric layer. The material of the tunneling dielectric layer 308a and the gate dielectric layer 308b is silicon oxide, for example. Obviously, the material and thickness of the tunneling dielectric layer 308a and the gate dielectric layer 308b can be identical or different. The material of the floating gate 310a and the select gate 310b is doped polysilicon formed by performing a chemical vapor deposition process, for example.

As shown in FIGS. 4B and 5B, a doping implant is performed to form lightly doped regions 312a, 312b, and 312c in the substrate 300. The doping implant is, for example, a process of using an ion implant method to implant dopants into the substrate 300. Thereafter, spacers 314a and 314b are formed on the sidewalls of the gate structure 306a and the gate structure 306b. The material of the spacers 314a and 314b is, for example, silicon oxide, silicon nitride or silicon oxynitride. The method of forming the spacers 314a and 314b includes, for example, performing a chemical vapor deposition process to form an insulating material layer and removing a portion of the insulating material layer by performing an anisotropic etching process.

Thereafter, using the gate structures 306a and 306b and their spacers 314a and 314b as a mask, a dopant implant process is performed to form heavily doped regions 316a, 316b and 316c in the substrate 300. The dopant implant process includes, for example, performing an ion implant process to implant dopants in the substrate 300. The lightly doped region 312a and the heavily doped region 316b together constitute a source/drain region 318a; the lightly doped region 312b and the heavily doped region 316b together constitute a source/drain region 318b; and the lightly doped region 312c and the heavily doped region 316c together constitute a source/drain region 318c. The gate structure 306a, the source/drain region 318a and the source/drain region 318b together constitute the floating gate transistor. The gate structure 306b, the source/drain region 318b and the source/drain region 318c together constitute the select gate transistor.

As shown in FIGS. 4C and 5C, a specific dielectric layer 320 is formed on the substrate 300. The specific dielectric layer 320 is a film that serves as a self-aligned salicide block oxide (SAB) or a resistive-protective oxide in a logic process, for example. In other words, the dielectric layer 320 is a film used in a self-aligned silicide process to cover areas where a silicide layer is not required so as to prevent a silicide reaction. This means that the specific dielectric layer 320 and the SAB in the logic process belong to the same type of process and there is no need to form the specific dielectric layer 320 in another process. Therefore, the non-volatile memory of the present invention can be fabricated without changing the conventional CMOS process. The material of the specific dielectric layer 320 is silicon oxide or silicon oxynitride, for example.

Thereafter, a mask layer 322 is formed on the substrate 300. The mask layer 322 covers the dielectric layer 320 over the gate structure 306a. The material of the mask layer 322 is photoresist, and the method of forming the mask layer 322 includes performing a spin-coating process to coat a layer of photoresist on the substrate 300 and performing a photolithographic process. Obviously, the masking layer 322 can be fabricated using other material.

As shown in FIGS. 4D and 5D, using the masking layer 322 as a mask, a portion of the dielectric layer 320 is removed so as to retain only a dielectric layer 320a over the gate structure 306a. The method of removing a portion of the dielectric layer 320 includes performing a wet etching operation using hydrofluoric acid as an etching agent, for example. Thereafter, the masking layer 322 is removed.

Thereafter, an inter-layer insulating layer 324 is formed on the substrate 300. The material of the inter-layer insulating layer 324 is phosphosilicate glass or borophosphosilicate glass, for example.

Conductive plugs 326, 328 and 330 are formed in the inter-layer insulating layer 324. The conductive plug 328 and the conductive plug 330 are electrically connected to the source/drain region 318a and the source/drain region 318c, respectively. The conductive plug 326 is located above the floating gate 310a and is connected to the dielectric layer 320a. The conductive plug 326 serves as an erase gate. The steps for forming the conductive plugs 326, 328 and 330 are as follows. First, the inter-layer insulating layer 324 is patterned to form plug openings that expose the dielectric layer 320a, the source/drain region 318a and the source/drain region 318b. Thereafter, the plug openings are filled using a conductive material.

In an embodiment of the present invention, a conductive plug is formed on top of the floating gate to serve as an erase gate. Furthermore, a specific dielectric layer (a self-aligned salicide block oxide or a resistive-protective oxide) is used as an inter-layer dielectric layer between the floating gate and the conductive plug (the erase gate). Therefore, the non-volatile memory can be fabricated without changing the conventional CMOS process. Moreover, the conductive plug (the erase gate) is directly disposed on the inter-layer dielectric layer above the floating gate. Therefore, the integration of the semiconductor devices can be effectively increased and yet the semiconductor devices do not occupy any additional space or additional masking layers.

In summary, in the non-volatile memory, a conductive plug disposed on the inter-layer dielectric layer above the floating gate to serve as an erase gate. Furthermore, a specific dielectric layer (a self-aligned salicide block oxide or a resistive-protective oxide) is used as an inter-layer dielectric layer between the floating gate and the conductive plug (the erase gate). Moreover, the conductive plug can be simultaneously formed together with the conductive plugs for connecting with the source/drain regions of the transistors. As a result, the non-volatile memory can be fabricated without changing the conventional CMOS process. In addition, the integration of the semiconductor devices can be effectively increased, and the semiconductor devices do not occupy additional space.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A non-volatile memory, disposed on a substrate, comprising:
an isolation structure, disposed in the substrate to define an active region;
a floating gate transistor, disposed on the substrate, comprising:
a floating gate, disposed on the substrate, running across the active region;
a tunneling dielectric layer, disposed between the floating gate and the substrate; and
a first source/drain region and a second source/drain region, disposed in the substrate at two sides of the floating gate, respectively;
a specific dielectric layer, disposed on the floating gate; and
an erase gate, disposed on said specific dielectric layer, wherein the erase gate consists of a first conductive plug, landing on said the specific dielectric layer.

2. The non-volatile memory according to claim 1, wherein the specific dielectric layer covers a portion of the floating gate.

3. The non-volatile memory according to claim 1, wherein the specific dielectric layer completely covers the floating gate.

4. The non-volatile memory according to claim 1, wherein material of the specific dielectric layer comprises silicon oxide or silicon oxynitride.

5. The non-volatile memory according to claim 1, wherein the erase gate is disposed at one end of the floating gate and located above the isolation structure.

6. The non-volatile memory according to claim 1, further comprising a second conductive plug and a third conductive plug electrically connected to the first source/drain region and the second source/drain region, respectively.

7. The non-volatile memory according to claim 1, further comprising a select gate transistor disposed on the substrate and serially connected to the floating gate transistor, the select gate transistor comprising:
a select gate, disposed on the substrate, running across the active region;
a gate dielectric layer, disposed between the select gate and the substrate; and
a third source/drain region and the second source/drain region, disposed in the substrate at two sides of the select gate, respectively.

8. The non-volatile memory according to claim 7, further comprising a second conductive plug and a third conductive plug electrically connected to the first source/drain region and the third source/drain region, respectively.

9. A method of fabricating non-volatile memory, comprising:
providing a substrate having a floating gate transistor formed thereon, wherein the floating gate transistor comprises a floating gate, a tunneling dielectric layer, a first source/drain region and a second source/drain region;
forming a specific dielectric layer on the substrate;
removing a portion of the specific dielectric layer so as to retain only a remaining portion of the specific dielectric layer above the floating gate; and
forming a first conductive plug on the specific dielectric layer, wherein the first conductive plug serves as an erase gate.

10. The method according to claim 9, wherein the step of removing a portion of the specific dielectric layer so as to retain only a remaining portion of the specific dielectric layer above the floating gate comprises:
forming a masking layer over the substrate to cover the floating gate;
removing a portion of the specific dielectric layer using the masking layer as a mask; and
removing the masking layer.

11. The method according to claim 9, further comprising forming an inter-layer insulating layer on the substrate before the step of forming the first conductive plug upon the specific dielectric layer.

12. The method according to claim 9, wherein the specific dielectric layer covers a portion of the floating gate.

13. The method according to claim 9, wherein the specific dielectric layer completely covers the floating gate.

14. The method according to claim 9, further comprising forming a select gate transistor on the substrate serially connected to the floating gate transistor, wherein the select gate transistor comprises a select gate, a gate dielectric layer and a third source/drain region and the second source/drain region.

15. The method according to claim 14, wherein the step of removing a portion of the specific dielectric layer so as to retain only a remaining portion of the specific dielectric layer above the floating gate comprises:
forming a masking layer over the substrate to cover the floating gate, removing the portion of the specific dielectric layer using the masking layer as a mask; and
removing the mask layer.

16. The method according to claim 14, further comprising forming an inter-layer insulating layer on the substrate before forming the first conductive plug upon the specific dielectric layer.

17. The method according to claim 14, wherein the specific dielectric layer covers a portion of the floating gate.

18. The method according to claim 14, wherein the specific dielectric layer completely covers the floating gate.

19. The method according to claim 14, wherein the step of forming the first conductive plug on the specific dielectric layer further comprises forming a second conductive plug and a third conductive plug for electrically connecting the first source/drain region and the third source/drain region, respectively.

20. The method according to claim 14, wherein material of the specific dielectric layer comprises silicon oxide or silicon oxynitride.
